(19) United States
(12) Patent Application Publication
(10) Pub. No.: US 2013/0312908 A1
(43) Pub. Date: Nov. 28, 2013

(54) METHOD FOR PRODUCING MODULES

(71) Applicant: Leopold Mader, Neuhofen/Ybbs (AT)

(72) Inventor: Leopold Mader, Neuhofen/Ybbs (AT)

(73) Assignee: INOVA LISEC TECHNOLOGIEZENTRUM GMBH, Seotemstettem (AT)

(21) Appl. No.: 13/984,173

(22) PCT Filed: Jan. 9, 2012
(86) PCT No.: PCT/AT2012/000004

§ 371 Date: Aug. 7, 2013

(30) Foreign Application Priority Data
Feb. 21, 2011 (AT) A 229/2011

(51) Int. Cl. H01L 31/18

(52) U.S. Cl. CPC H01L 31/18
USPC 156/285

(57) ABSTRACT

In order to produce photovoltaic modules or modules bearing functional coatings, a strand (3) composed of sealing composition is arranged along the outer edge of a glass sheet (1) and at least one photovoltaic cell (11) and/or at least one functional coating, for example a light-emitting coating, are/is applied within the strand (3). As a next step, a composition (13) is applied to the glass sheet (1) within the strand (3). A second glass sheet (3) is then placed onto the strand (3) at a distance from the free surface (5) of the strand (3) and the arrangement is evacuated. The evacuated arrangement is compressed in a heating press, such that the entire interior space (9) between the glass sheets (1) and (2) and within the sealing strand (3) is filled by composition (13), which is a pasty gel-like composition e.g. a resin, or a silicone-based composition.

The invention relates to a method for producing modules, which contain components, in particular electrical components, such as photovoltaic cells or functional layers, between two glass disks.

Previously, during production of photovoltaic modules, the procedure was such that the photovoltaic cells in the modules were arranged between films. This mode of operation has the drawback that it is not always ensured that all of the air has been removed from the modules, which should be designed as vacuum elements.

The object of the invention is to propose a mode of operation with which modules of the above-mentioned type can be produced simply and easily.

This object is achieved according to the invention with a method that has the features of claim 1.

Preferred and advantageous configurations of the invention are subjects of the subclaims.

Since, in the method according to the invention, an amount of pasty/gel-like composition, e.g., a resin, which corresponds to the final volume of the space between the two glass panels, is filled into the space within the sealing strand, which is arranged along the outside edge of one glass panel, in which also at least one component, such as a photovoltaic cell or a functional layer, is contained in the one glass disk, a simplified mode of operation is produced that ensures that the entire space is filled with the composition (the resin) without residual air pockets.

The resin is preferably a casting resin, which can be introduced in viscous, pasty, or granulate-type form. In this case, a curing casting resin can preferably be used, which consists of one, two or more than two components.

The distribution of the casting resin can be supported by heating and/or by oscillations, in particular ultrasonic oscillations.

Instead of casting resin, other pasty/gel-like compositions, e.g., silicone-based compositions, can also be used.

Other details and features of the method of the invention follow from the description given below of a diagrammatic process sequence with exemplary production of photovoltaic modules based on the drawings.

Here:

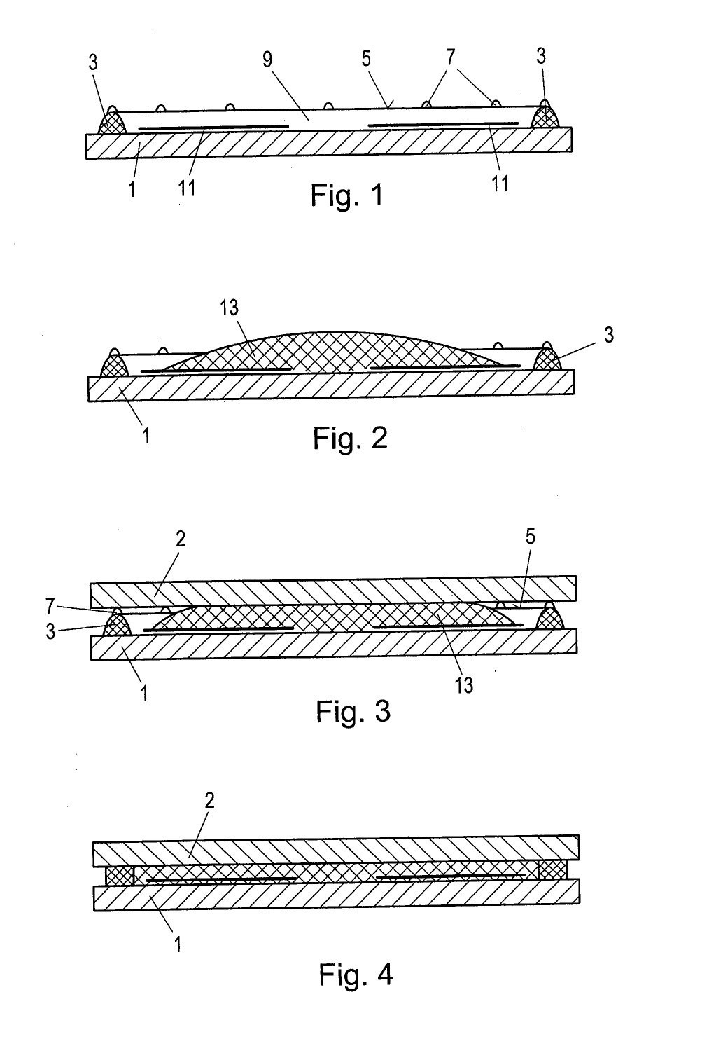

FIGS. 1 to 4 diagrammatically show the stages of a first variant of the method according to the invention, and

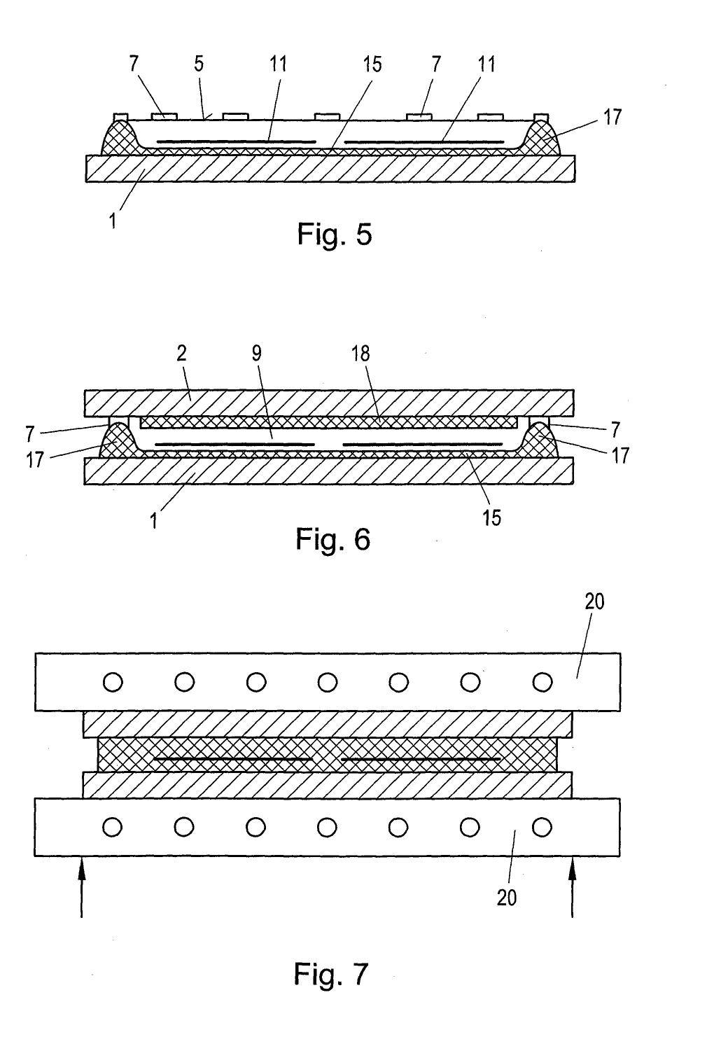

FIGS. 5 to 7 show the stages of a modified embodiment of the method according to the invention.

First, a strand 3 that consists of sealing composition is applied to a glass disk 1 (base disk) along its periphery. This strand 3 has projections 7 on its free surface 5 that faces away from the glass disk 1.

At least one component, in the embodiment one photovoltaic cell 11, but preferably several photovoltaic cells 11, is/are placed within the space 9 edged by the strand 3 (FIG. 1).

In the next step, an amount of casting resin 13 corresponding to the final volume of the space 9 between the glass disks 1 and 2 and within the strand 3 is introduced within the area bordered by the strand 3 (FIG. 2).

As soon as this has taken place, a second glass disk 2 (cover disk) is brought into position as the next step, whereby between the second glass disk 2 and the strand 3, an interval that allows the evacuation exists at at least one spot (FIG. 3). This interval is produced in the embodiment shown in FIGS. 1 to 4 in that the second glass disk 2 first rests on the projections 7 provided on the free surface 5 of the strand 3, as is indicated in FIG. 3.

Instead of projections 7 on the strand 3 that consists of sealing composition, there is also in principle the possibility in the free surface 5 of the strand 3 to provide at least one recess that allows the evacuation of the space 9 between the glass disks 1 and 2 and within the strand 3.

The thus formed arrangement is brought into a vacuum chamber and evacuated.

During the evacuation, or as soon as the desired vacuum is reached, the arrangement can be heated and/or can be put into oscillation (ultrasonic oscillation) in order to support the distribution of the casting resin 13.

In the vacuum chamber, the second glass disk 2 (cover disk) is then brought toward the lower glass disk 1 (base disk), and the arrangement—which consists of the glass disks 1, 2, the strand 3 made of sealing composition, and the photovoltaic cells 11—is pressed in such a way that only the casting resin 13 and the photovoltaic cells 11 are contained between the glass disks 1, 2 within the space 9 that is defined by the strand 3, which now connects the glass disks 1, 2 to one another.

Within the framework of the invention, consideration is given that instead of photovoltaic cells 11 on a glass disk 1 or 2 or two glass disks 1 and 2, functional layers are provided as components both for the method variant according to FIGS. 1 to 4 and the method variant, described below, according to FIGS. 5 to 7. Such functional layers can be, for example, layers that emit light when electrical voltage is applied, so that the arrangement (module) that is obtained according to the method of the invention can be used as a luminescent agent.

In the variant of the method according to the invention that is depicted in FIGS. 5 to 7, the procedure is such that a layer 15 that consists of gel-like or pasty composition, e.g., a silicone-based composition, is applied on the first glass disk 1 (base disk). In the variant of the method according to the invention that is shown in FIGS. 5 to 7, consideration is given in addition to forming the strand on the edge of the glass disk 1 in one piece with the layer 15 that consists of gel-like or pasty composition, as is shown in FIG. 5 for the strand 17.

Also, in the embodiment according to FIGS. 6 to 7, projections 7 are provided on the free surface 5 of the strand 17, and said projections are formed in particular from material of the strand 17, i.e., that consists of pasty or gel-like composition. It should be pointed out that instead of photovoltaic cells 11 on the glass disk 1, functional layers can be provided (not shown).

In the arrangement according to FIG. 5, in the next step of the method variant, the second glass disk 2 is brought into position covering the glass disk 1, whereby the glass disk 2 rests on the projections 7 with its surface facing toward the glass disk 1, so that as in the method variant according to FIGS. 1 to 4 (see FIG. 3), there is a gap between the free surface 5 of the strand 17 and the glass disk 2, and the inner space 9 can be evacuated.

In the variant shown in FIGS. 5 to 7, it is provided in addition that a portion of the composition that is partially introduced into the inner space 9 of the finished arrangement (module) that consists of two glass disks 1, 2 and the photovoltaic cells 11 or functional coatings on one or both of the glass disks 1 and 2 is provided in such a way that on the surface of the glass disk 2 that faces toward the glass disk 1, a layer that consists of gel-like or pasty coating 18 is provided.

The arrangement, as it is shown in FIG. 6, is evacuated until the desired underpressure prevails in the inner space 9 of the arrangement. This arrangement is then introduced between hot plates 20 of a press, and after the heating, the lower hot plate 20 is pushed forward onto the upper hot plate 20 so that the arrangement is pressed, and finally the finished arrangement (module) in FIG. 7 (depicted still between the hot plates 20) is produced, in which the entire inner space 9 between the glass disks 1 and 2 is filled with gel-like or pasty composition coming from the layers 15 and 18.

In this variant, consideration is given here that the arrangement according to FIG. 6 is pressed wide after the evacuation in such a way that the second glass disk 2 is no longer arranged at a distance from the free end surface 5 of the strand 17 but rather rests on the strand 17 over its entire periphery without interruption, so that when inserting the arrangement between the hot plates 20 of the heating press according to FIG. 7, the vacuum remains unchanged.

In summary, an embodiment of the invention can be described as follows.

For the production of photovoltaic modules or modules that bear functional coatings, a strand 3 that consists of sealing composition is arranged along the outside edge of a glass disk 1, and at least one photovoltaic cell 11 and/or at least one functional coating, for example a light-emitting coating, is/are applied within the strand 3. As a next step, a composition 13 is applied within the strand 3 to the glass disk 1. On the strand 3, a second glass disk 2 is then placed at a distance from the free surface 5 of the strand 3, and the arrangement is evacuated. The evacuated arrangement is compressed in a heating press, so that the entire inner space 9 between the glass disks 1 and 2 as well as within the sealing strand 3 is filled by composition 13, which is a pasty, gel-like composition, e.g., a resin, or a composition based on silicone.

1. Method for producing modules that consist of two glass disks (1, 2) between which at least one photovoltaic cell (11) and/or one functional layer is provided, characterized in that on the edge of a first glass disk (1), a strand (3, 17) is applied, in that in the area within the strand (3, 17), a composition (13, 15, 18) is arranged, in that a second glass disk (2) is placed on the strand (3, 17) at a distance allowing evacuation of the inner space (9) between the glass disks (1, 2), in that the thus obtained arrangement is evacuated, and in that the glass disks (1, 2) are brought toward one another until the entire inner space is filled by the composition (13, 15, 18), and the inner space (9) is sealed laterally by the strand (3, 17).

2. Method according to claim 1, wherein projections (7) are provided on the free surface (5) of the strand (3, 17).

3. Method according to claim 1 claims 1 and 2, wherein at least one recess is provided in the free edge (5) of the strand (3, 17).

4. Method according to claim 1, wherein a pasty, gel-like composition is used as the composition (13, 15, 18).

5. Method according to claim 4, wherein a resin, in particular a casting resin, is used as the composition (13, 15, 18).

6. Method according to claim 4, wherein a composition based on silicone is used as the composition.

7. Method according to claim 1, wherein the composition (13, 15, 18) is introduced in viscous, pasty or granulate-type form into the area (9) within the strand (3, 17).

8. Method according to claim 4, wherein the composition in the form of layers (15, 18) is introduced onto the first glass disk (1) and/or the second glass disk (2).

9. Method according to claim 1, wherein when the glass disks (1, 2) are brought together, the distribution of the composition (3, 15, 18) into the space (9) between the glass disks (1, 2) is supported by heating and/or by generation of oscillations.

10. Method according to claim 1, wherein the strand (17) on the edge of the first glass disk (1) consists of the same material as the composition (15).

11. Method according to claim 2, wherein at least one recess is provided in the free edge (5) of the strand (3, 17).

12. Method according to claim 2, wherein a pasty, gel-like composition is used as the composition (13, 15, 18).

13. Method according to claim 3, wherein a pasty, gel-like composition is used as the composition (13, 15, 18).
